(19) United States
(12) Patent Application Publication
(10) Pub. No.: US 2006/0163696 A1
(43) Pub. Date: Jul. 27, 2006

(54) Metal base transistor and oscillator using the same

(75) Inventors: Kazuhiro Mochizuki, Tokyo (JP); Shigehisa Tanaka, Kokubunji (JP); Tomonori Tanoue, Machida (JP)

Correspondence Address: Stanley P. Fisher;Reed Smith LLP, Suite 1400, 3110 Fairview Park Drive, Falls Church, VA, 22042-4503, US

(73) Assignee: Hitachi, Ltd.

(21) Appl. No.: 11/208,561

(22) Filed: Aug. 23, 2005

(30) Foreign Application Priority Data
Jan. 26, 2005 (JP) 2005-017724

(51) Int. Cl. H01L 27/082

(52) U.S. Cl. 257/565

(57) ABSTRACT

The most important task in realizing a downsized and low cost THz band spectroscopic and fluoroscopic instrument is to achieve downsizing and cost reduction of oscillators used in the instrument. A metal base transistor is used for an active element of the oscillator. In order to improve the maximum oscillation frequency of the transistor to several THZ, InN having a high electron saturation velocity or a material mainly composed of InN is used for a collector layer. In order to obtain characteristics with excellent reproducibility, it is useful to insert InGaN into an interface between the collector layer and the base layer. Using the metal base transistor of the present invention makes it possible to constitute an oscillator allowing a THz band oscillation. Further, the present invention provides a spectroscopic instrument applying this oscillator to at least one of a signal source and a local oscillator.

The present application claims priority from Japanese application JP 2005-017724, filed on Jan. 26, 2005, the content of which is hereby incorporated by reference into this application.

### BACKGROUND OF THE INVENTION

1. Field of the Invention

The present invention relates to an ultra-high-speed transistor and an oscillator using the same.

2. Description of the Related Art

As the needs of dangerous article detection increase, a terahertz (THz) band spectroscopic technique capable of nondestructively identifying a substance attracts attention. Further, the effective utilization of the THz band is already verified by a method of using light for a light source, such as a free electron laser, a p-type germanium laser, light injection type parametric generation and optical mixing on the optical switching. The comparison of these techniques is disclosed, for example, in Japanese Society of Radiological Technology Academic Journal Vol. 58, No. 4 (2002), pp. 441-447 (Non-Patent Document 1). However, these techniques have a problem in that if the THz band spectroscopic instrument is formed by the method of using light for a light source, formation of a large-sized instrument at a higher cost is inevitable, and responses to market needs such as formation of a small-sized instrument at a lower cost are impossible.

On the other hand, with the main aim of reducing the cost, there is disclosed a method for frequency multiplying the output of a millimeter wave band oscillator such as a Gunn diode oscillator or an IMPATT diode oscillator by a GaAs Schottky diode. However, the method has the following two problems; (1) a frequency multiplier is jumbo-sized, and (2) the output is reduced from an output level of the millimeter wave band oscillator by several figures, which makes it difficult to gain an output required for a spectroscopic instrument. Accordingly, there has been desired a technique for realizing, at a lower cost by using a semiconductor process, a downsized oscillator that directly oscillates in terahertz bands. However, it is difficult to realize a maximum oscillation frequency of several THz, which is required for the direct oscillation, by using the conventional semiconductor technique.

When considering, as candidates for an active device used in oscillators, a high electron mobility transistor (HEMT) and heterojunction bipolar transistor (HBT) on an InP substrate having excellent high frequency characteristics as compared with a Si substrate, the following facts are found. That is, although both the transistors have a maximum oscillation frequency of several hundreds GHz at most, the heterojunction bipolar transistor (HBT) is suitable for realization of downsizing and high-performance. The reason is as follows: the HBT is a vertical device and further, can be increased in power density as well as can be reduced in phase noise due to surface recombination. Consequently, the present inventors consider the possibilities of applying, to an active device for a THz band oscillator, a metal base transistor (Metal Base Transistor: hereinafter abbreviated to an MBT) which is a vertical device similar to the HBT and of which the maximum oscillation frequency is maximized.

Heretofore, high frequency characteristics of the MBT are not reported; however, a configuration of the MBT with a current gain increased up to 20,000 is disclosed in Applied Physics Letters, Vol. 77, No. 5 (2000), pp, 753 to 755 (Non-Patent Document 2). In the document, the MBT having a collector-top configuration is formed on a sapphire substrate 21, as shown in FIG. 14. The MBT comprises a subemitter 22 composed of a high-doped n-type GaN, an emitter 23 composed of an n-type GaN, a base 24 composed of W, a collector 25 composed of WO₃ which is formed by oxidizing a base metal, a collector electrode 26, a base electrode 27 and an emitter electrode 28.

[Non-Patent Document 1]

Japanese Society of Radiological Technology Academic Journal Vol. 58, No. 4 (2002), pp. 441-447

[Non-Patent Document 2]

Applied Physics Letters Vol. 77, No. 5 (2000), pp. 753-757

### SUMMARY OF THE INVENTION

A conventional MBT has a problem in that a cutoff frequency thereof is relatively low. A principal factor thereof is that a depletion layer electron velocity in a collector composed of WO₃ is as low as the order of 10⁶ cm/s. Such a value of the velocity makes the cutoff frequency of the MBT lower than that of the conventional HBT. As a result, several THz as a maximum oscillation frequency required for a THz band spectroscopic instrument cannot be realized. Accordingly, the biggest technical object of the present invention is to improve the depletion layer electron velocity.

In addition, another object of the present invention is to provide an oscillator useful for realizing a downsized low-cost THz band spectroscopic instrument.

To accomplish the above objects of the present invention, according to first means of the invention, there is provided a metal base transistor comprising: a first substrate; a collector layer; a base layer; and an emitter layer, the collector layer, the base layer and the emitter layer being sequentially laminated on the first substrate; wherein the collector layer comprises n-type InN or an n-type semiconductor material having an InN mole fraction of 0.5 or more, and the base layer comprises metal.

In order to obtain this metal base transistor with excellent reproducibility, according to second means of the present invention, it is preferred that n-type InGaN having an InN mole fraction of less than 0.5 or p-type InGaN having an InN mole fraction of 0.5 or more is inserted into an interface between the collector layer and base layer of the MBT.

In order to make the first means and the second means more effective, according to third means of the present invention, it is useful that a thickness in an MBT intrinsic region (a region immediately underneath the emitter electrode, which is essential to transistor operations) of the base layer is made smaller than that in an MBT extrinsic region (an MBT region other than that immediately underneath the emitter electrode) and is set to a value corresponding to one atom layer or more.

Further, in order to more simply realize the third means with excellent reproducibility, according to fourth means of the present invention, it is useful to use a metal oxide constituting the base layer, for the emitter layer. In particular, the most preferred combination of specific materials is aluminum used for the base layer and an aluminum oxide used for the emitter layer. Further, combinations of W and W oxide, Mo and Mo oxide, Hf and Hf oxide, and Zr and Zr oxide are preferred.

The oscillator of the present invention comprises: a first substrate including a monolithic integrated circuit having an oscillator array and at least one of a resistor, a capacitor, an inductor and a transmission line formed thereon, the oscillator array having at least one frequency; and a second substrate having at least one external terminal of the monolithic integrated circuit; wherein the first substrate and the second substrate are electrically bonded through a bump electrode. The oscillator or the oscillator array is used for at least one of a signal source and a local oscillator of spectroscopic instrument.

### BRIEF DESCRIPTION OF THE DRAWINGS

FIG. 1 is a longitudinal sectional view of a metal base transistor according to a first embodiment of the present invention;

FIG. 2 is a longitudinal sectional view of a metal base transistor according to a second embodiment of the present invention;

FIG. 3 is a longitudinal sectional view of a metal base transistor according to a third embodiment of the present invention;

FIG. 4 is a longitudinal sectional view showing a first step of a manufacturing method for an MBT according to a fourth embodiment of the present invention;

FIG. 5 is a longitudinal sectional view showing a step, subsequent to the step in FIG. 4, of the manufacturing method for the MBT according to the fourth embodiment of the present invention;

FIG. 6 is a longitudinal sectional view showing a step, subsequent to the step in FIG. 5, of the manufacturing method for the MBT according to the fourth embodiment of the present invention;

FIG. 7 is a longitudinal sectional view showing a step, subsequent to the step in FIG. 6, of the manufacturing method for the MBT according to the fourth embodiment of the present invention;

FIG. 8 is a longitudinal sectional view showing a step, subsequent to the step in FIG. 7, of the manufacturing method for the MBT according to the fourth embodiment of the present invention;

FIG. 9 is a longitudinal sectional view showing a step, subsequent to the step in FIG. 8, of the manufacturing method for the MBT according to the fourth embodiment of the present invention;

FIG. 10 is a longitudinal sectional view showing a monolithic integrated circuit constituting an MBT oscillator according to a fifth embodiment of the present invention;

FIG. 11 is a longitudinal sectional view showing a mounting embodiment on a module substrate of the monolithic integrated circuit constituting the MBT oscillator according to the fifth embodiment of the present invention;

FIG. 12 is a longitudinal sectional view showing a mounting embodiment on a module substrate of the monolithic integrated circuit constituting an MBT oscillator array according to the fifth embodiment of the present invention;

FIG. 13 is a block diagram showing a configuration of the THz band spectroscopic instrument using the MBT oscillator according to the fifth embodiment of the present invention;

FIG. 14 is a longitudinal sectional view of a metal base transistor according to a conventional technique; and

FIG. 15 is a circuit diagram of an oscillator according to the present invention.

### DESCRIPTION OF THE PREFERRED EMBODIMENTS

Prior to detail explanations of various preferred embodiments of the present invention, configurations and features of the embodiments are additionally described.

The essence of the present invention is to use an n-type InN or an n-type semiconductor having an InN mole fraction of 0.5 or more for a collector layer of an MBT. An embodiment as the essence of the present invention uses these materials to improve a depletion layer electron velocity in the collector layer to the order of 10⁷ cm/s. The electron velocity increases up to 4×10⁷ cm/s particularly in an InN collector layer. As a result, a carrier transit time in the collector depletion layer is greatly reduced so that a cutoff frequency of the MBT can be improved.

Accordingly, a maximum oscillation frequency of 2 THz required for an oscillator used for a THz band spectroscopic instrument can be realized.

Examples of the typical n-type semiconductor materials having the InN mole fraction of 0.5 or more include InₓGa₁₋ₓN (x>0.5), InₓAl₁₋ₓN (x>0.5) and InₓGa_{y}Al_{1-x-y}N (x>0.5).

A substrate that has been heretofore used for the MBT, for example, a semiconductor substrate such as sapphire, SiC, Si or GaAs, or an amorphous substrate such as glass can be used for a first substrate. A base layer material that has been heretofore used for the MBT can be used also for metal of a base layer. Examples thereof include Al, W, Mo, Hf and Zr.

Further, a collector layer material that has been heretofore used for the MBT can be used also for the collector layer. Examples thereof include Al₂O₃, WO₃, MoO₂, HfO₂ and ZrO₂. The most preferable example is Al₂O₃ which is in cooperation with aluminum, metal of the above-described base layer.

Next, an improved second aspect is described. In this embodiment, second means inserts an n-type InGaN having an InN mole fraction of less than 0.5 or a p-type InGaN having an InN mole fraction of 0.5 or more into an interface between the collector layer and the base layer.

More specifically, the first means has a possibility that depending on a formation method of the InN layer, electrons are accumulated in the interface between the collector layer and the metal base layer, and as a result, defects may occur in diode operations in a base-collector junction. On the other hand, the second means has an advantage that even when the metal base layer is formed by use of any formation method such as evaporation, sputtering or chemical vapor deposition, electrons are prevented from being accumulated in the interface between the base layer and the collector layer, and as a result, the MBT having excellent reproducibility can be realized.

Next, third means relating to the improvement of the cutoff frequency is described. More specifically, the third means is an aspect in which a thickness in an intrinsic region of the base layer is set to a thickness of one atom layer or more, which is smaller than that in an extrinsic region. By doing so, both of a base transit time and a base resistance can be reduced. As a result, the improvement of cutoff frequencies can be attained. Further, an oscillator using the MBT can improve the maximum oscillation frequency to 3 THz or more.

A fourth means is an aspect where the embodiment of the third means can be more simply realized with excellent reproducibility. In the fourth means, a metal oxide constituting the base layer is used for an emitter layer. In this case, oxidizing the metal can simply realize the present embodiment with excellent reproducibility.

In this aspect, in addition to an aspect of the above-described manufacturing method, high-velocity hot electrons having a high energy are injected to the base layer from the emitter layer to improve a cutoff frequency. As a result, the maximum oscillation frequency also increases to 4 THz or more. This embodiment realizes the present invention more effectively.

Next, an oscillator as a second mode of the present invention is described.

An essence of the oscillator according to the present invention is as below. On the first substrate, a transistor required for the oscillator and at least one of desired electronic components such as a resistor, a capacitor, an inductor and a transmission line are formed to constitute a monolithic integrated circuit. Further, an oscillator array is incorporated into this integrated circuit. The MBT described in the foregoing is used as the transistors for the oscillator array. At the same time, a second substrate is prepared, on which a bump electrode is formed to allow these electronic elements to be bonded to external elements. Further, the first substrate and the second substrate are flip-chip bonded through the bump electrodes.

Further, the oscillator or oscillator array using the metal base transistor of the present invention is useful when being applied to constituents of a signal source or local oscillator of a spectroscopic and fluoroscopic instrument. Thus, the downsizing and cost reduction of the THz band spectroscopic and fluoroscopic instrument can be realized.

On the other hand, when an oscillator using the MBT manufactured is formed by the known technique, the oscillator is difficult to directly oscillate at a terahertz band. Therefore, a frequency multiplier using a GaAs schottky diode must be simultaneously used. Accordingly, using such an oscillator makes it impossible to reduce the size and cost of the THz band spectroscopic and fluoroscopic instrument.

### First Embodiment

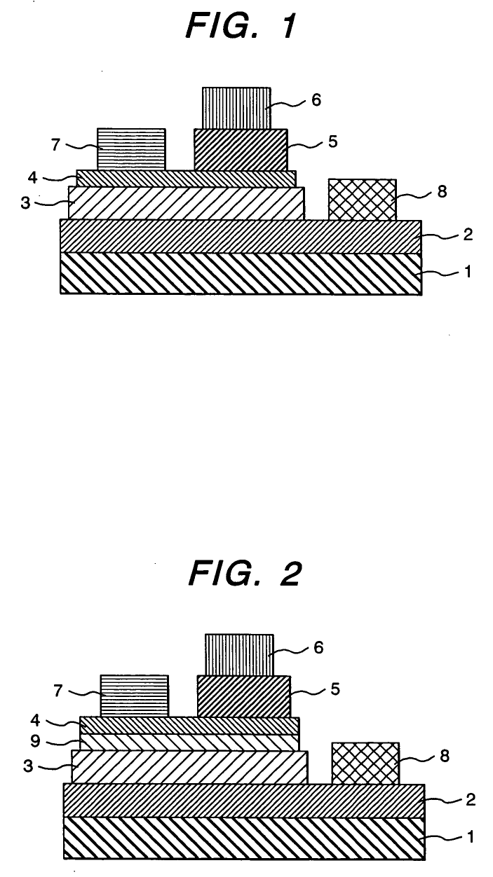

FIG. 1 is a longitudinal sectional view of an MBT according to a first embodiment of the present invention. The present embodiment employs an emitter-top configuration. Further, the present embodiment employs, for a collector, InN which is a material having an extremely high saturation velocity of electrons.

A layered mesa structure comprising a high concentration n-type doped InN subcollector layer (electron concentration: 5×10¹⁸ cm⁻³, thickness: 500 nm) 2, an n-type InN collector layer (electron concentration: 5×10¹⁶ cm⁻³, thickness: 500 nm) 3, an Al base layer (thickness: 5 nm) 4 and an Al₂O₃ emitter layer (thickness: 5 nm) 5 is formed on a sapphire substrate 1. In this mesa structure, an emitter electrode 6, a base electrode 7 and a collector electrode 8 each comprising Au/Pt/Ti are further formed on the emitter layer 5, the base layer 4 and the subcollector layer 2, respectively.

The present embodiment employs the emitter-top configuration in place of a conventional collector-top configuration. Further, the present embodiment employs a material having an extremely high electron saturation velocity of 4×10⁷ cm/s for the collector. As a result, a collector depletion-layer transit time of electrons is greatly reduced. Further, the maximum oscillation frequency of the MBT reaches 2 THz, which is required for the oscillator used for the THz band spectroscopic and fluoroscopic instrument.

Since the basic of the manufacturing method of this configuration is explained by a fourth embodiment, the detailed explanation is omitted herein. This configuration may be manufactured in accordance with the manufacturing method in the fourth embodiment.

In this embodiment, InN is used for forming the n-type collector layer 3. Also when a semiconductor material having an InN mole fraction of 0.5 or more is used, the high-speed electron transition in the collector depletion-layer of an order of 10⁷ cm/s can be realized. Therefore, formation of the collector layer using the semiconductor material can be of course performed in the same manner as in the above-described InN collector layer. The substrate 1 to be used is not limited to sapphire. A semiconductor substrate such as SiC, Si or GaAs, or an amorphous substrate such as glass may also be used as the substrate 1. When the amorphous substrate is used, the subcollector layer 2 and the collector layer 3 become polycrystal. However, the InN collector can provide semiconductor conduction in spite of polycrystal and therefore is applicable to the substrate.

### Second Embodiment

FIG. 2 is a longitudinal sectional view of the MBT according to a second embodiment of the present invention. As an intermediate layer 9, n-type InGaN having an InN mole fraction of less than 0.5 or p-type InGaN (thickness: 5 nm) having an InN mole fraction of 0.5 or more is inserted between the n-type InN collector layer 3 and Al base layer 4 of the first embodiment. Semiconductor layers other than the layer 9 are the same as those of the first embodiment.

The first embodiment has a problem in that depending on a formation method of the InN layer, electrons are accumulated in the interface between the collector layer and the metal base layer, and as a result, defects are found in diode operations in base-collector junction. This phenomenon is probably peculiar to materials containing plenty of In such as InN or InAs. On the other hand, according to the present embodiment, the In content at the interface between the base and the collector is reduced so that the accumulation of electrons can be avoided. As a result, an effect capable of realizing an MBT with excellent reproducibility of characteristics is obtained.

The p-type InGaN is low in p-type concentration. Therefore, even if the layer is depleted to have high resistance, there is no problem in view of operations of the MBT.

### Third Embodiment

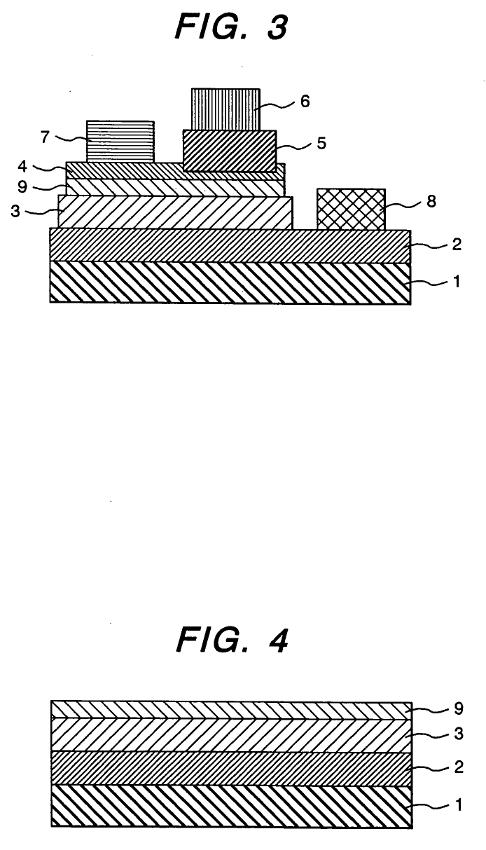

FIG. 3 is a longitudinal sectional view of the MBT according to a third embodiment of the present invention. A thickness of the base layer 4 in the first or second embodiments is set to 5 nm in the intrinsic region and 10 nm in the extrinsic region. As a result, the maximum oscillation frequency is improved up to 3 THz.

According to the present embodiment, both of the base transit time and the base resistance can be reduced. As a result, an effect capable of greatly improving the maximum oscillation frequency is obtained.

In the present embodiment, a thickness in the intrinsic region of the base layer 4 is set to 5 nm; however, the thickness may be set to a value corresponding to one atom layer or more.

### Fourth Embodiment

In a fourth embodiment, a metal oxide which constitutes the base layer 4 is used for the emitter layer 5 in the third embodiment. Accordingly, this embodiment comprises, in addition to a basic configuration of the present invention, the following each configuration. That is, the embodiment comprises (1) a configuration having the intermediate layer composed of InGaN; (2) a configuration of making a thickness in the transistor intrinsic region of the base layer smaller than that in the transistor extrinsic region, and (3) a configuration of using, for the emitter layer, a metal oxide constituting the base layer.

An example of the manufacturing method of the MBT in the present embodiment is described below with reference to FIGS. 4 to 9. First, by using a molecular beam epitaxial method, a high concentration n-type doped InN subcollector layer (electron concentration: 5×10¹⁸ cm⁻³, thickness: 500 nm) 2, an n-type InN collector layer (electron concentration: 5×10¹⁶ cm⁻³, thickness: 500 nm) 3 and an n-type InGaN intermediate layer (InN mole fraction: 0.6, electron concentration: 5×10¹⁶ cm⁻³, thickness: 5 nm) 9 are sequentially grown on a sapphire substrate 1 at the substrate temperature of 350° C. (FIG. 4).

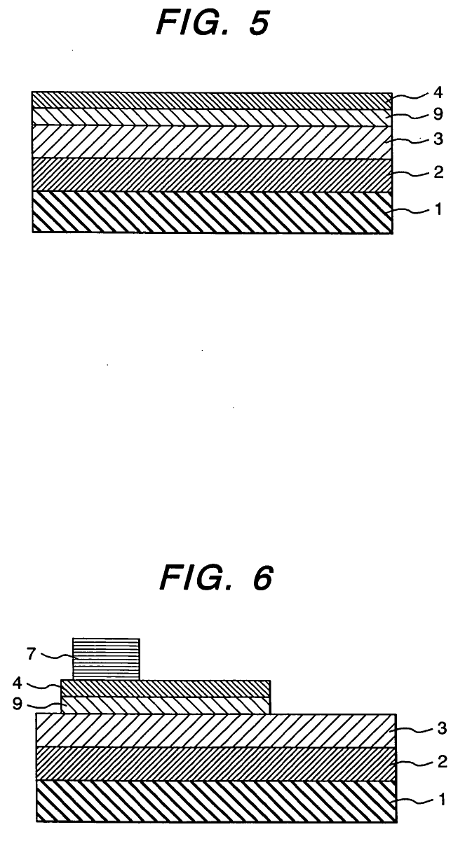

Subsequently, the substrate temperature is reduced up to 150° C. and an Al base layer (thickness: 10 nm) 4 is grown inside the molecular beam epitaxial apparatus (FIG. 5).

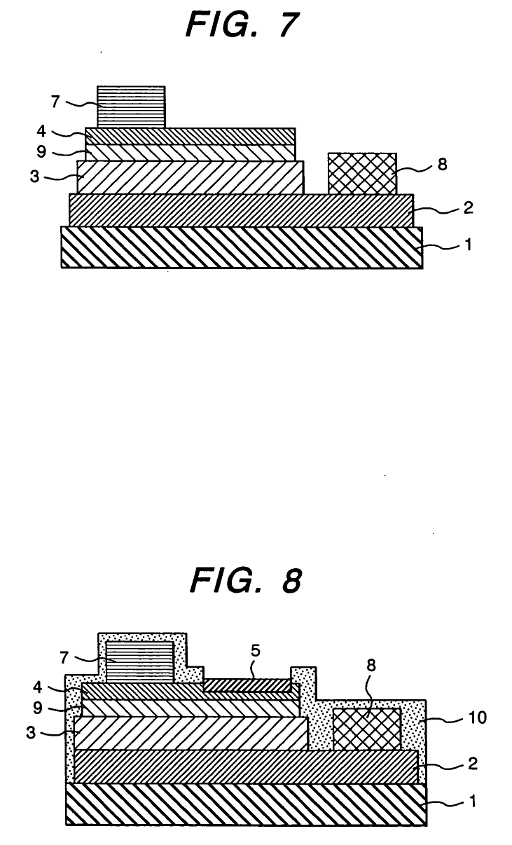

Thereafter, the specimen is taken out from the molecular beam epitaxial apparatus and then the Al base layer 4 and the intermediate layer 7 are selectively etched by photolithography and dry etching. Further, an Au/Pt/Ti base electrode is formed by the liftoff method (FIG. 6). Subsequently, an Au/Pt/Ti collector electrode is formed by the liftoff method (FIG. 7).

Further, an Al₂O₃ emitter 5 is formed as below (FIG. 8). That is, by using the chemical vapor deposition method, the whole MBT is covered with an insulating film (thickness: 20 nm) 10 such as a SiO₂ film. Further, only the emitter region is opened by photolithography and dry etching. Then, the emitter region is oxidized at a temperature of 200° C. for 30 minutes using ozone generated by ultraviolet rays (usually, referred to as a UV ozone oxidation (UVO₃ oxidation)). On this occasion, the emitter 5 is formed to a thickness of 5 nm and the intrinsic base underneath the emitter 5 is formed to a thickness of 5 nm.

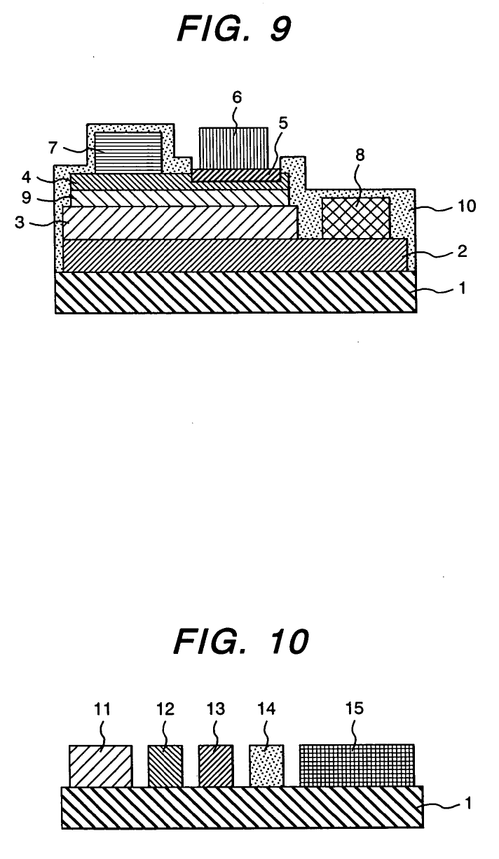

Finally, an Au/Pt/Ti emitter electrode is formed using the liftoff method. Thus, the MBT is completed (FIG. 9).

According to the present embodiment, since the metal oxide constituting the base layer of the MBT described in the third embodiment is used for the emitter layer, the third means can be simply realized with excellent reproducibility by using an oxidation process.

### Fifth Embodiment

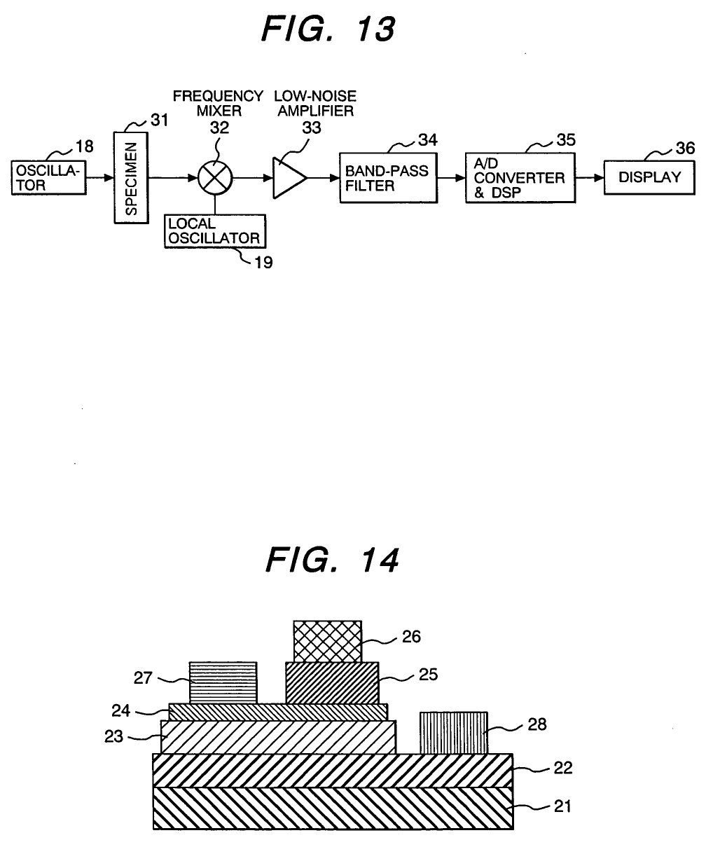

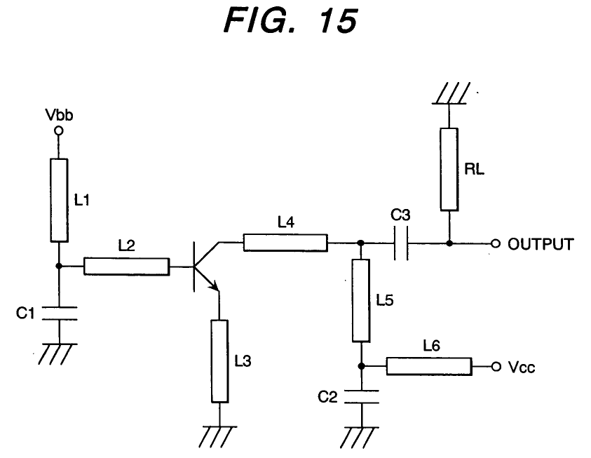

Examples of the oscillator and oscillator array of the present invention are illustrated with reference to FIGS. 10 to 12. Further, an application of the oscillator and oscillator array to the spectroscopic instrument is illustrated by referring to FIG. 13.

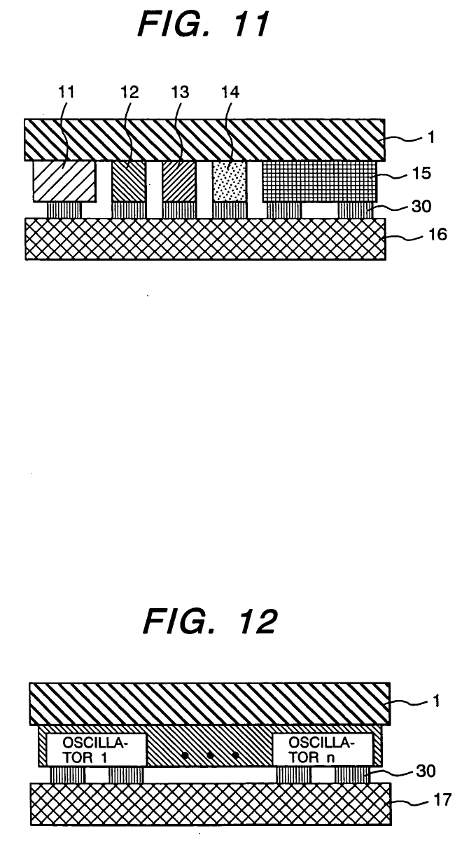

The substrate 1 having at least the MBT 11 formed thereon is prepared. In this case, any one of the MBTs described in the first to fourth embodiments may be used for the MBT 11 according to the required characteristics. On the substrate 1 having the MBT 11 formed thereon, for example, a resistor 12, a capacitor 13, an inductor 14 and a transmission line 15 are formed to constitute a monolithic integrated circuit (FIG. 10). The reason why the passive element or the transmission line is made monolithic is that in view of dealing with a THz band signal, a signal delay is excessively increased in a hybrid integrated circuit. FIG. 11 shows a configuration in which the monolithic integrated circuit is subjected to surface passivation and then is flip-chip bonded through bumps 30 to a module substrate 16 made of, for example, ceramics or resins. Herein, the reason why the mounting is performed using flip-chip bonding instead of wire bonding is to reduce characteristic deterioration due to parasitic components such as a parasitic inductance otherwise caused by the wire bonding.

FIG. 15 is a circuit diagram of the oscillator according to the present invention. Symbols L1, L2, L3, L4, L5, L6 and RL are each composed of the transmission line 15. Symbols L1 and L6 are transmission lines for bias supplying a base voltage Vbb and a collector voltage Vcc, respectively, to a THz signal under sufficiently high impedance. Further, symbols L2 and L3 are transmission lines for generating a negative resistance at the collector end of the MBT. To the contrary, symbols L4 and L5 are transmission lines for constituting a matching circuit used for maximizing an output in the load resistor RL (50Ω in the present embodiment). Symbols C1, C2 and C3 are capacitors for removing DC components. In the present embodiment, the widths and lengths of transmission lines L2 and L3 are changed and the changed widths and lengths are combined with one another, thereby realizing an oscillator having an oscillation frequency of 1 to 3 THz.

The real THz band spectroscopic instrument is required to deal with an oscillation frequency of 1 to 3 THz as well as a single oscillation frequency. Therefore, the oscillators used in the THz band spectroscopic instrument must be arrayed. In FIG. 12, the oscillators 1 to n (n is an integer) having different oscillation frequencies are arrayed in the monolithic integrated circuit. Further, the respective I/O terminals and power terminals of the oscillators 1 to n are mounted by flip-chip bonding with a module substrate 17.

These oscillators or oscillator arrays can be applied to an oscillator or local oscillator of the THz band spectroscopic instrument. FIG. 13 is a block diagram showing an example of the THz band spectroscopic instrument.

In the THz band spectroscopic instrument of FIG. 13, THz radiation emitting from an oscillator 18 is incident on a specimen 31. Reflected light or transmitted light from the specimen 31 is introduced into a frequency mixer 32. In the mixer 32, the reflected light or transmitted light is multiplied by an output of a local oscillator 19. A difference frequency signal as an output from the mixer 32 is amplified by a low-noise amplifier 33 to pass through a band-pass filter 34. Thereafter, the signal is subjected to analog-digital conversion and to digital signal processing in an A/D converter & DSP (digital signal processor) 35. Then, the resultant signal is displayed on a display 36. Accordingly, the oscillator or oscillator array of the present invention can be applied, for example, to the oscillator 18 or local oscillator 19 of the THz band spectroscopic instrument shown in FIG. 13.

According to the present embodiment, the downsized and low-cost THz band spectroscopic instrument using the downsized and low-cost oscillator 18 and local oscillator 19 can be realized without using a frequency multiplier.

The present invention is applicable to an ultra-high-speed transistor and an apparatus using the same as well as to a metal base transistor and an oscillator using the same.

As described in detail above, the MBT of the present invention can realize a high cutoff frequency. Thus, according to use of the MBT of the present invention, an oscillator having the maximum oscillation frequency of several THz can be provided.

According to another aspect of the present invention, an oscillator useful for realizing a downsized and low cost THz band spectroscopic instrument can be provided.

A description of reference numerals will be made below.

1, 21 . . . Sapphire substrate, 2 . . . Subcollector layer, 22 . . . Subemitter layer, 5, 23 . . . Emitter layer, 4, 24 . . . Base layer, 3, 25 . . . Collector layer, 8, 26 . . . Collector electrode, 7, 27 . . . Base electrode, 6, 28 . . . Emitter electrode, 9 . . . InGaN intermediate layer, 10 . . . Insulating layer, 11 . . . Metal base transistor, 12 . . . Resistor, 13 . . . Capacitor, 14 . . . Inductor, 15 . . . Transmission line, 16, 17 . . . Module substrate, 18 . . . Oscillator, 19 . . . Local oscillator, 30 . . . Bump, 31 . . . Specimen, 32 . . . Frequency mixer, 33 . . . Low-noise amplifier, 34 . . . Band-pass filter, 35 . . . A/D converter & DSP, 36 . . . Display.

What is claimed is:

1. A metal base transistor comprising:
a first substrate;
a collector layer;
a base layer; and
an emitter layer, the first layer, the collector layer and the base layer being sequentially laminated on the first substrate;
wherein the collector layer comprises an n-type InN or an n-type semiconductor material having an InN mole fraction of 0.5 or more, and the base layer comprises metal.

2. The metal base transistor according to claim 1, wherein any one of an n-type InGaN layer having an InN mole fraction of less than 0.5 or a p-type InGaN layer having an InN mole fraction of 0.5 or more is inserted into an interface between the collector layer and base layer of the MBT.

3. The metal base transistor according to claim 1, wherein in the base layer, a thickness in a transistor intrinsic region is smaller than that in a transistor parasitic region and is one atom layer or more.

4. The metal base transistor according to claim 3, wherein a metal oxide constituting the base layer is used for the emitter layer.

5. The metal base transistor according to claim 4, wherein the base layer comprises aluminum and the emitter layer comprises an aluminum oxide.

6. The metal base transistor according to claim 5, wherein the base layer comprises aluminum and the emitter layer comprises an aluminum oxide.

7. An oscillator comprising:
a first substrate including a monolithic integrated circuit having an oscillator array and at least one electric member formed thereon, the oscillator array including a plurality of oscillator each having at least a metal base transistor formed thereon; and
a second substrate having at least one external terminal of the monolithic integrated circuit;
wherein the first substrate and the second substrate are electrically bonded through a bump electrode; and
wherein the metal base transistor according to claim 1 is used as the metal base transistor formed on the first substrate.

8. A spectroscopic instrument using the metal base transistor according to claim 1 for at least one of constituent elements of a signal source and a local oscillator.

9. A spectroscopic instrument using the metal base transistor according to claim 7 for at least one of a signal source and a local oscillator.
